(19) United States
(12) Patent Application Publication
(10) Pub. No.: US 2001/0050103 A1
(43) Pub. Date: Dec. 13, 2001

(54) Solar cell and process for producing the same

(76) Inventor: Hidetoshi Washio, Kashihara-shi (JP)

Correspondence Address: NIXON & VANDERHYE P.C., 8th Floor, 1100 North Glebe Rd., Arlington, VA, 22201-4714, US

(21) Appl. No.: 09/870,444

(22) Filed: Jun. 1, 2001

(30) Foreign Application Priority Data
Jun. 6, 2000 (JP) 2000-169197

(51) Int. Cl. H01L 21/00; H01L 31/00

(52) U.S. Cl. 136/256; 136/252; 438/57

(57) ABSTRACT

A solar cell comprising a substrate having cleavage directions perpendicular to each other and having textures arranged on its light-receiving surface, said textures having bottom sides adjacent to each other along the cleavage directions and the bottom sides along at least one cleavage direction being discontinuous.

### CROSS-REFERENCE TO RELATED APPLICATION

This application is related to Japanese Patent Application No. 2000-169197 filed in Jun. 6, 2000, whose priority is claimed under 35 USC §119, the disclosure of which is incorporated by reference in its entirety.

### BACKGROUND OF THE INVENTION

1. Field of the Invention

The present invention relates to a solar cell having textures arranged on a light-receiving surface of a substrate having cleavage directions perpendicular to each other, and a process for producing the same.

2. Description of the Related Art

FIG. 6 shows an example of a cross sectional view of a solar cell.

The solar cell 100 is generally called as an NRS/BSF (non-reflective surface/back surface field) type solar battery and comprises a P type silicon substrate 4 having on a light-receiving surface thereof an N⁺ type diffusion layer 3, which is formed by thermal diffusion of an N type impurity, for effectively incorporating carriers generated by light energy. An oxide film layer 7 is formed on the N⁺ type diffusion layer 3 to reduce recombination of the carriers on the surface, and a surface electrode 2 of a comb form is formed on an opening part, on which the oxide film layer 7 is not formed, for effectively taking out electricity thus generated, which is directly connected to the N⁺ type diffusion layer 3. Furthermore, the substantially entire surface of the light-receiving surface of the solar cell 100 except for an N electrode connecting part not shown in the figure is covered with a reflection preventing film 10 for reducing surface reflection of the incident light.

Uneven textures 8 of an inverted pyramid shape to reduce surface reflection are formed on the surface of the substrate 4 as described later.

The N⁺ type diffusion layer 3, the oxide film layer 7 and the reflection preventing film 10 are sequentially formed in conformance with the profile of the textures 8.

A P⁺ type diffusion layer 5 is formed on the back surface of the P type silicon substrate 4 by thermal diffusion of a P type impurity for increasing the amount of carriers, and under the layer, an oxide film layer 7 for reducing recombination of the carriers and a back surface electrode 6 for reflecting long wavelength light escaping away from the back surface and for taking out electricity thus generated are formed over the substantially entire surface of the layer. The P⁺ type diffusion layer 5 and the back surface electrode 6 are connected to each other through an opening not shown in the figure formed in the oxide film layer 7.

In the solar cell 100 of an NRS/BSF type shown in FIG. 6, the textures 8 formed on the light-receiving surface serves to allow multiple reflection of incident light to increase the amount of light reaching the interior of the cell, and because the size, the formed area and the configuration thereof exhibit great influence on the output power by changing the electric energy thus generated, it is an extremely important factor how the size and the shape of the textures 8 are to be configured.

In other words, as shown in FIG. 7, the incident light is subjected to multiple reflection on the light-receiving surface by the textures 8, so as to reduce the surface reflectivity. As a result, the amount of light absorbed by the substrate 4 is increased, and thus a larger amount of an electric current can be generated. Particularly, in the case of a solar cell for use in the space, which is irradiated with radioactive rays (cosmic rays), when it has the textures 8 on the substrate 4, the average thickness of the substrate is decreased, and the incident light is refracted at the light-receiving surface to be incident on the substrate in an oblique direction due to the presence of the textures 8, whereby the carriers generated in the vicinity of the PN junction formed in the vicinity of the surface of the solar cell is increased, and the influence on the lifetime of the carrier caused by radiation degradation can be reduced. Accordingly, the textures 8 formed on a larger area of the light-receiving surface is effective for the improvement of the output of the solar cell.

Therefore, the conventional solar cell 100 has configurations of the textures 8, for example, shown in FIGS. 8, 9, 10(a) and 10(b). FIG. 8 is a plane view showing the entire solar cell 100, FIG. 9 is an enlarged plane view showing the part shown by symbol A in FIG. 8, and FIG. 10(a) is an enlarged plane view showing the part shown by symbol B in FIG. 9. In FIGS. 8 and 9, numeral 12 denotes a grid electrode of the surface electrode 2, 16 denotes a bar electrode of the surface electrode 2, and 14 denotes a connector (pad) electrode for taking out an output electric power.

The textures 8 are arranged in a grid form on the entire region of the solar cell 100 except for a part where the surface electrode 2 is formed and edge parts of the solar battery, and the respective textures 8 are inverted pyramid shape depressions having a square plane view and having the same quadrangular pyramid shape of the same size as shown in FIG. 10(a). In FIGS. 10(a) and 10(b), numeral 20 in the right lower part thereof shows the cleavage directions of a wafer constituting the substrate 4.

Furthermore, as shown in FIG. 10(b), the textures 8 may be formed in a different direction depending on the difference in crystalline direction of the substrate 4. In this example, the direction of forming the textures 8 deviates from the case shown in FIG. 10(a) by 45°.

In order to form the textures 8 having the shape shown in FIGS. 10(a) and 1(b), the steps shown in FIGS. 11(a) to 11(g), for example, have been conventionally conducted.

As shown in FIG. 11(a), a silicon substrate 4 having plane azimuth (100) is prepared. As shown in FIG. 11(b), an oxide film layer 7 is formed on the surface of the silicon substrate 4 by thermal oxidation or CVD. As shown in FIG. 11(c), a resist 15 is coated on the upper surface and the lower surface of the oxide film layer 7. As shown in FIG. 11(d), the resist 15 on the light-receiving surface is exposed to predetermined patterns for textures and alignment marks, followed by development, so as to form the patterns of the textures and the alignment marks not shown in the figures are formed with the resist 15 on the oxide film layer 7.

As shown in FIG. 11(e), the unnecessary part of the oxide film layer 7 is removed, for example, by etching, and then the resist 15 is removed, so as to form a texture pattern with the oxide film layer 7 on the silicon substrate 4. As shown in FIG. 11(f), the substrate in this state is subjected to etching with an etching solution of a predetermined temperature and a predetermine concentration, such as an alkali solution at a high temperature, for a predetermined period of time. In the case of the silicon substrate 4, respective crystal faces have different rates of corrosion with a chemical reagent, and the textures 8 of a fine inverted pyramid shape can be formed by anisotropic etching utilizing the difference. At this time, the alignment marks are formed to have a concave shape (not shown in the figures). As shown in FIG. 11(g), finally, the oxide film layer 7 is removed to form the textures 8 and the alignment marks (not shown in the figures) are formed on the light-receiving surface of the silicon substrate 4.

The textures 8 of the inverted pyramid shape shown by the perspective view of FIG. 12 can be obtained through the foregoing steps. The textures 8 are formed on the entire region of the light-receiving surface (the upper surface in the figure) of the solar cell 100 except for the part where the surface electrode 2 is formed and the edge parts of the cell. The N⁺ type diffusion layer 3, the oxide film layer 7 and the reflection preventing film 10 are sequentially formed in conformance with the profile of the textures 8.

However, the solar cell 100 having the conventional textures 8 has such problems that it suffers large warpage during production and it is liable to be cracked. The reasons of the problems will be described below.

In the arrangement structure of the conventional textures 8, when a silicon wafer having a plane azimuth (100), for example, is used as a substrate, the textures 8 shown in FIGS. 10(a) and 10(b) are continuously formed in two directions perpendicular to each other by utilizing the anisotropic etching. Because both the two directions agree to the cleavage directions of the wafer constituting the silicon substrate 4, the wafer having the textures 8 formed thereon is liable to be warped and to be cracked in the cleavage directions in comparison to a wafer having no texture formed. Therefore, deterioration of productivity and contamination of a production line caused by fragments of broken silicon substrates 4 occur upon production of the solar cell.

### SUMMARY OF THE INVENTION

The invention has been developed in view of the circumstances, and an object of the invention is to provide a solar cell having a texture structure having suppressed crack and warpage, and a process for producing the same.

The invention relates to a solar cell comprising a substrate having cleavage directions perpendicular to each other and having textures arranged on its light-receiving surface, said textures having bottom sides adjacent to each other along the cleavage directions and the bottom sides along at least one cleavage direction being discontinuous.

That is, in the case where a substrate having continuous cleavage directions in two directions perpendicular to each other, such as a silicon wafer of a plane azimuth (100), is used, and textures adjacent to each other at the bottom sides thereof are formed on the surface of the substrate, the bottom sides are prevented from aligning in a straight line in the two cleavage directions, whereby breakage and warpage of the solar cell can be suppressed with the conventional anisotropic etching utilized.

In the invention, the term “texture” referred herein means a non-reflective surface shape having been conventionally used in a solar cell. The textures may have a surface shape exhibiting a reflectivity of a light-receiving surface of about 10% or less to light having a wavelength of from 0.5 to 1.0 μm without a reflection preventing film with respect to a reflectivity of a mirror surface being 100%, and preferably, a surface shape that reflects substantially no light by absorbing light. Examples of the shape include a square opening having a dent of an inverted pyramid shape and an opening having a dent of a V-shape groove. The solar battery of the invention has a structure of numerous minute textures formed on the light-receiving surface. The textures of the invention may have an inverted pyramid shape having a bottom of a rectangular shape or a polygonal shape.

Further the term “texture” herein means an opening above explained having at least one light-receiving surface.

The term “discontinuous bottom sides” referred herein means such an arrangement of textures that a straight line of the bottom sides by meeting the edges (apices) of the bottoms is not formed, and the line of the bottom sides does not come across from end to end of the substrate in at least one of the cleavage directions of the substrate.

In other words, it is sufficient that there is a part where the bottoms do not connect at the edges thereof in at least one of the cleavage directions of the substrate.

The invention includes, for example, the following embodiments of the arrangement of the textures from the standpoint of the size and the arrangement of the bottoms.

In one embodiment shown in FIGS. 1(a) and 1(b), bottom sides of adjacent textures are discontinuous in one cleavage direction, and the bottom sides along the discontinuous cleavage direction have the same length. In another embodiment shown in FIGS. 2(a) and 2(b), bottom sides of adjacent textures are discontinuous in one cleavage direction, and the bottom sides along the discontinuous cleavage direction have different lengths. In a further embodiment shown in FIGS. 3(a) and 3(b), bottom sides of adjacent textures are discontinuous in one cleavage direction, and the bottom side of at least one of the textures adjacent to each other in the discontinuous cleavage direction has a different length.

In the constitutions of the embodiments shown in FIGS. 1A, 1B, 3A and 3B, the textures are arranged in such a manner that the deviation of the adjacent textures in the direction, in which the bottom sides are discontinuous, is ½ of the length of the bottom side of one texture. The deviation is not limited to ½ of the length of the bottom side of one texture but can be arbitrary set.

In the three embodiments, the arrangement direction of the textures may be changed depending on the crystallographic azimuth of the wafer constituting the substrate. That is, when the texture forming region is formed on the rectangular substrate, the invention includes not only the case where the direction of one side of the substrate agrees to the cleavage direction, but also the case where one side of the substrate forms a prescribed angle with respect to the cleavage direction.

In another aspect, the invention relates to a process for producing textures of a solar cell comprising a step of: forming an oxide film layer on a light-receiving surface of a substrate having cleavage directions perpendicular to each other; forming a masking pattern of the oxide film layer using a photo resist; and etching the light-receiving surface of the substrate using the masking pattern, thereby forming an arrangement of textures on the surface of the substrate; the masking pattern being formed so that the textures have bottom sides adjacent to each other along the cleavage directions and the bottom sides along at least one cleavage direction are discontinuous.

### BRIEF DESCRIPTION OF THE DRAWINGS

FIGS. 1(a) and 1(b) are plane views showing examples of the arrangement of the textures in the solar cell according to the invention;

FIGS. 2(a) and 2(b) are plane views showing other examples of the arrangement of the textures in the solar cell according to the invention;

FIGS. 3(a) and 3(b) are plane views showing further examples of the arrangement of the textures in the solar cell according to the invention;

FIGS. 4(a), 4(b) and 4(c) are cross sectional view showing steps before and after etching for forming textures having bottom sides of different length in the case where the line widths of the masking pattern are the same as each other irrespective to the size of the textures;

FIGS. 5(a) and 5(b) are cross sectional view showing steps before and after etching for forming textures having bottom sides of different length in the case where the line widths of the masking pattern are changed corresponding to the size of the textures;

FIG. 6 is a cross sectional view showing an example of a solar cell;

FIG. 7 is a diagram showing reflection and refraction of light on the surface of the textures;

FIG. 8 is a plane view showing an example of a solar cell;

FIG. 9 is an enlarged plane view showing the part shown by symbol A in FIG. 8;

FIGS. 10(a) and 10(b) are enlarged plane views showing part shown by symbol B in FIG. 9, which are examples of a structure of textures of a conventional solar cell;

FIGS. 11(a) to 11(g) are cross sectional views showing an example of a production process of textures of a solar cell; and

FIG. 12 is a perspective view showing an example of a conventional solar cell.

### DESCRIPTION OF THE PREFERRED EMBODIMENTS

Embodiments of the solar cell according to the invention will be described with reference to the drawings, but the invention is not construed as being limited to the embodiments.

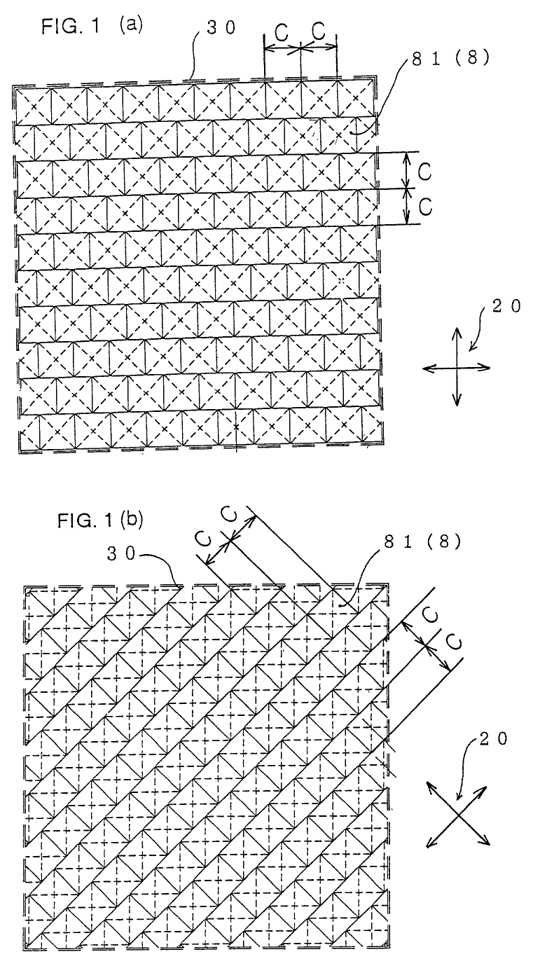

FIGS. 1(a), 1(b), 2(a), 2(b), 3(a) and 3(b) are plane views showing specific examples of the arrangement of the textures the solar cell. In these embodiments, the textures are arranged on the light-receiving surface of the substrate having cleavage directions perpendicular to each other, and a region 30 for forming the textures is of a rectangular shape on the substrate.

In FIG. 1(a), the textures 8 contain textures 81 having a regular quadrangular pyramid shape having bottom sides C of the same length arranged in the texture forming region 30 in the vertical and horizontal directions in such a manner that the textures 81 are adjacent to each other at the bottom sides C, and the bottom sides C in the vertical direction in the figure is formed to be discontinuous. In other words, the textures 81 are arranged in such a manner that the bottom sides C do not align in a straight line in at least one of the cleavage directions 20.

The length of the deviation of the textures 8 is not particularly limited, and in the case where it is ½ of the length of the bottom side C as shown in FIG. 1(a), occurrence of cracking and warpage of the solar cell can be effectively prevented.

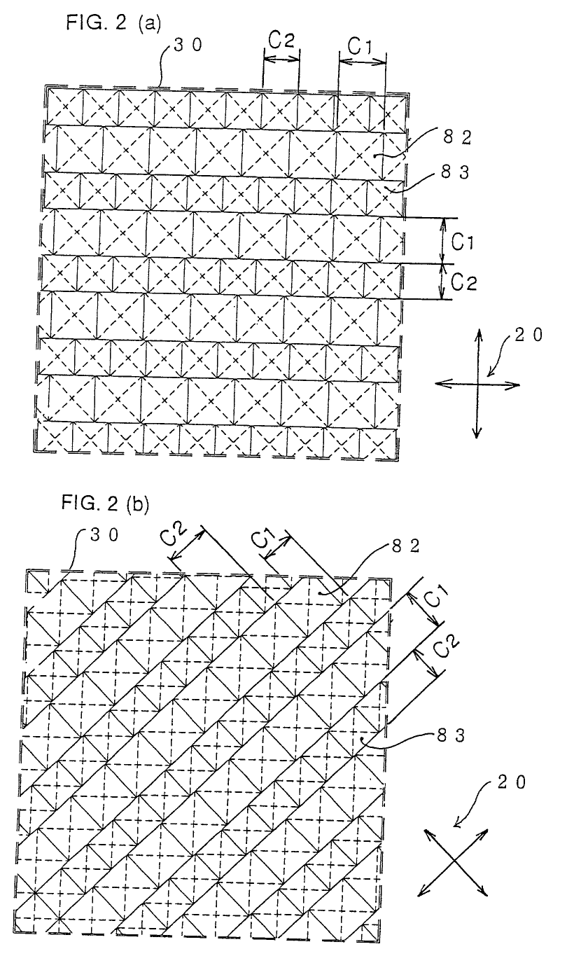

In FIG. 2(a), the textures 8 contain textures 82 and 83 each having regular quadrangular pyramid shapes having bottom sides C1 and C2 of different lengths arranged in the texture forming region 30 in the vertical and horizontal directions in such a manner that the textures 82 and 83 each are adjacent to each other at the bottom sides C1 and C2, and the bottom sides C1 and C2 in the vertical direction in the figure are formed to be discontinuous.

In other words, while lines formed by adjacently arranging the larger textures 82 in the vertical direction and lines formed by adjacently arranging the smaller textures 83 are alternately continued in the figure, the textures 82 and 83 are arranged in such a manner that the bottom sides C1 and C2 do not align in a straight line in at least one of the cleavage directions 20.

The length of the deviation of the textures 82 and 83 are changed depending on the difference of the lengths of the bottom sides C1 and C2.

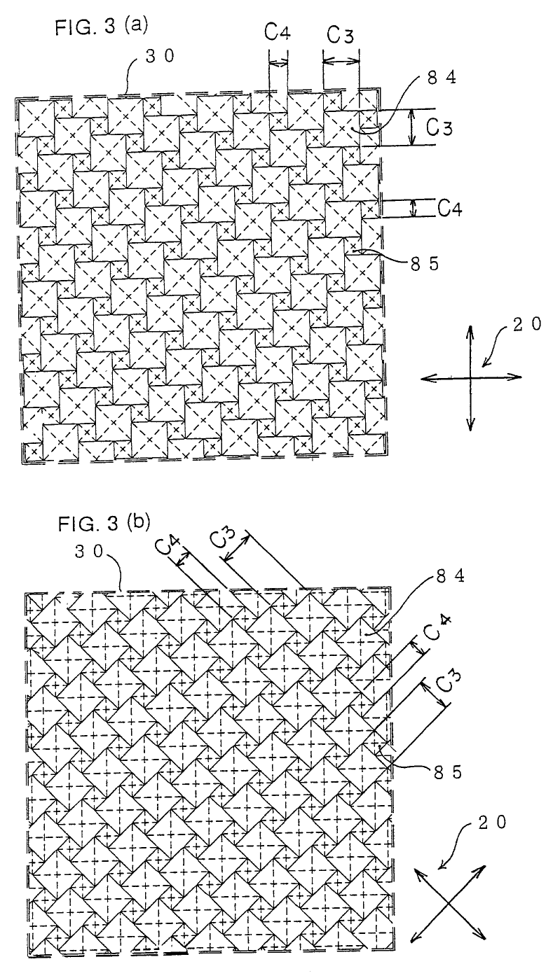

In FIG. 3(a), the textures 8 contain textures 84 and 85 each having regular quadrangular pyramid shapes having bottom sides C3 and C4 of different lengths arranged in the texture forming region 30 in the vertical and horizontal directions in such a manner that the textures 82 and 83 each are adjacent to each other at the bottom sides C3 and C4, and the bottom sides C3 and C4 in the vertical direction and the horizontal direction in the figure are formed to be discontinuous.

In other words, the larger textures 84 and the smaller textures 85 are arranged to surrounding each other but do not continuously align in the horizontal direction. The bottom side C4 of the textures 85 has a length that is a half of the bottom side C3 of the textures 84, and the textures 82 and 83 are arranged in such a manner that the bottom sides C3 and C4 do not align in a straight line in both the cleavage directions 20.

The length of the deviation of the textures 84 and 85 is not particularly limited, and in the case where it is ½ of the length of the bottom side C3 as shown in FIG. 3(a), occurrence of cracking and warpage of the solar cell can be effectively prevented.

There are cases where the arrangement direction of the texture is changed depending on the crystallographic azimuth of the wafer constituting the substrate. While the direction of one side of the region 30 for forming the textures 8 (81 to 85) agrees to the cleavage direction in the embodiments shown in FIGS. 1(a), 2(a) and 3(a), it is also possible that the direction of one side of the region 30 for forming the textures 8 (81 to 85) forms a prescribed angle with respect to the cleavage direction 20.

In the case where the textures that are adjacent to each other at the bottom sides of C, C1, C2, C3 and C4 are formed on the surface of the substrate having the cleavage directions 20 continuous in two directions perpendicular to each other as shown by the foregoing embodiments, the bottom sides are prevented from aligning in a straight line in the two cleavage directions 20, whereby occurrence of cracking and warpage of the solar cell can be suppressed. Such an arrangement of the textures 8 can be formed by utilizing the conventional anisotropic etching only with a pattern of a glass mask being changed as described later.

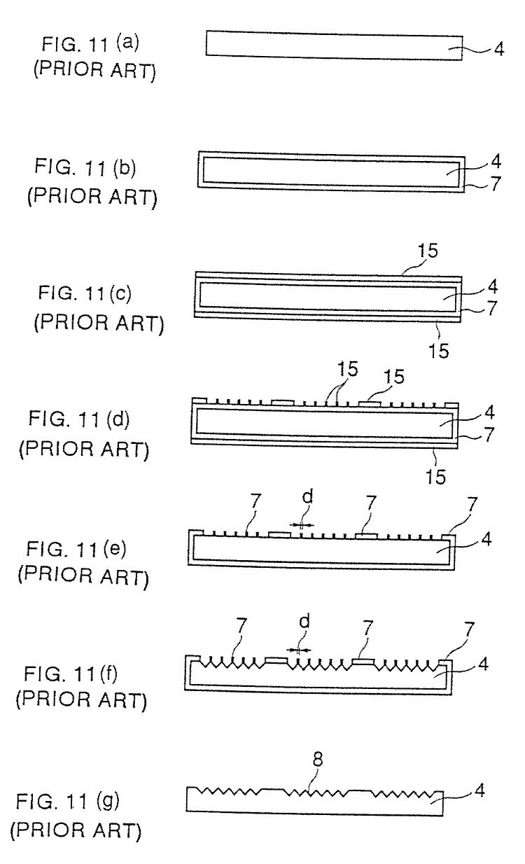

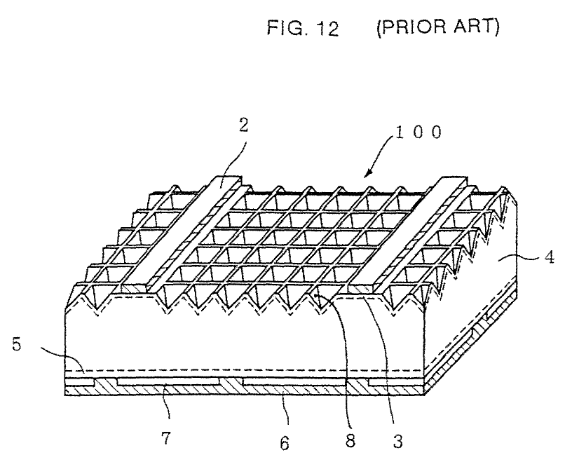

The textures 8 shown in FIGS. 1(a), 1(b), 2(a), 2(b), 3(a) and 3(b) can be produced by the productions steps of the conventional textures 8 shown in FIGS. 11(a) to 11(g), but the shape of the masking pattern used is different from the conventional one. The production steps will be described below.

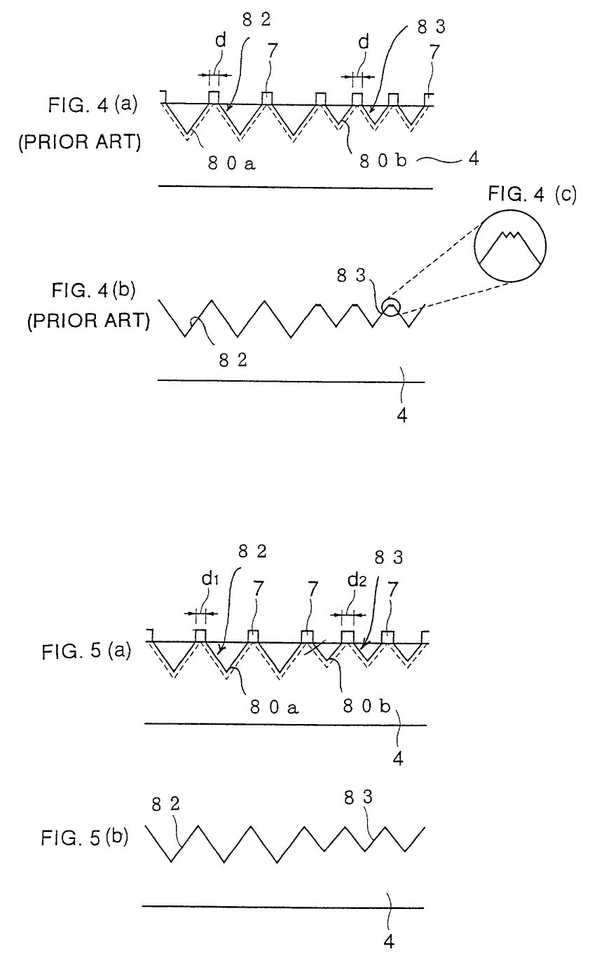

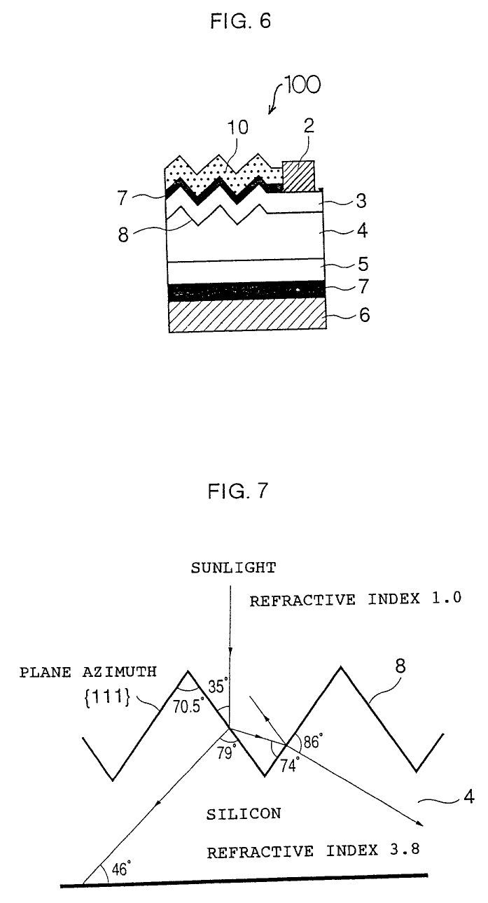

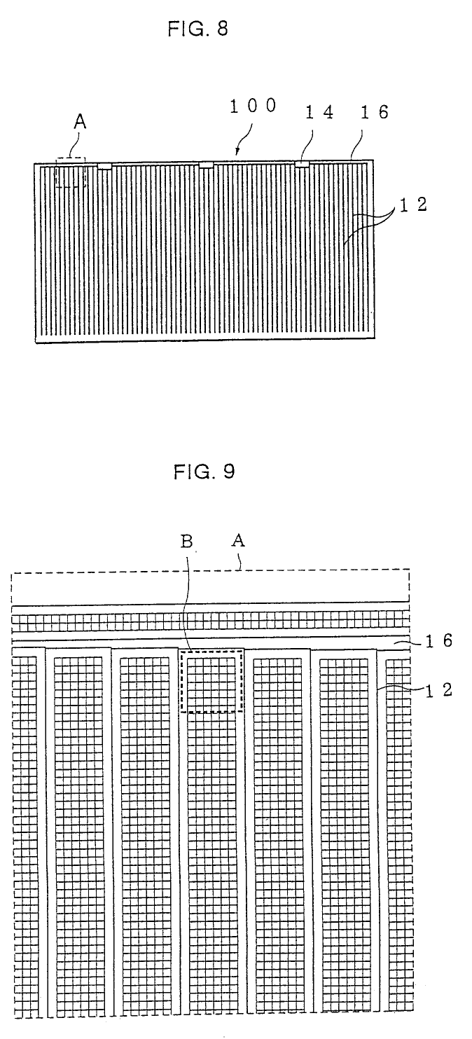

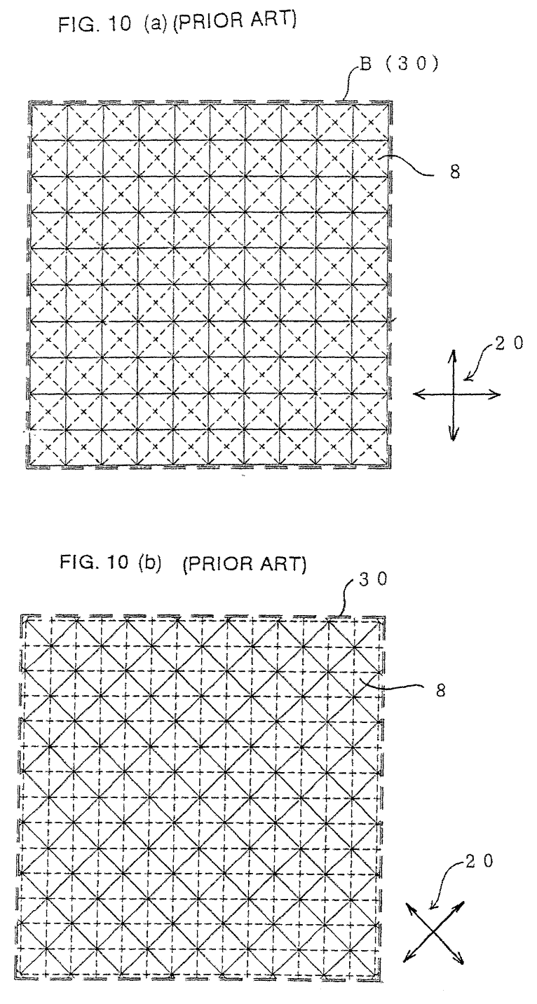

FIGS. 4(a) to 4(c), 5(a) and 5(b) are cross sectional views showing steps before and after etching for forming textures having different sizes (for example, the textures 82 to 85 shown in FIGS. 2(a), 2(b), 3(a) and 3(b)) by the etching step of the silicon substrate 4 shown in FIG. 11(f).

FIGS. 4(a) and 4(c) show the case where an oxide film layer 7 as a masking pattern having the same line width d irrespective to the size of the textures 8 is used for forming the textures 8, and FIGS. 5(a) and 5(b) show the case where the line width of the oxide film layer 7 is changed to d1 and d2 (d1<d2) corresponding to the size of the textures 8.

As shown in FIG. 4(a), etching proceeds to the part shown by the solid lines under the state where the oxide film layer 7 as the masking pattern having the same line width d is formed on the silicon substrate 4, and when floors 80a and 80b appear, etching starts to proceed in the vertical direction. At this time, since the (111) plane exposed by the etching exhibits a larger etching rate than the (100) plane (not shown in the figures), the etching rate having been constant is then changed into such a state that the horizontal etching rate is larger than the downward one. The etching is then conducted until the apices of the quadrangular pyramids shown by the broken lines are formed, and in this case, the horizontal etching of the smaller textures, for example, the textures 83, becomes overetching at the time when the etching of the larger textures, for example, the textures 82, is completed, whereby the apices of the smaller textures 83 are lost. As a result, after removing the oxide film layer 7, the designed texture shape cannot be formed for the smaller textures 83 as shown in FIG. 4(b) and an enlarged view thereof, FIG. 4(c), whereby the output power is slightly lowered, and appearance failure may occur.

On the other hand, in the case where the line width of the oxide film layer 7 is changed to d1 and d2 (d1<d2) as shown in FIGS. 5(a) and 5(b), etching proceeds to the part shown by the solid lines under the state where the oxide film layer 7 as the masking pattern having the different line widths is formed on the silicon substrate 4, and when floors 80a and 80b appear, etching starts to proceed in the vertical direction. At this time, the etching rate having been constant is then changed into such a state that the horizontal etching rate is larger than the downward one. The etching is then conducted until the apices of the quadrangular pyramids shown by the broken lines are formed. In this case, because the line width d2 of the oxide film layer 7 for the smaller textures 83 is larger than the line width d1 of the oxide film layer 7 for the larger textures 82, the etching of the smaller textures 83 can be completed simultaneously with the time when the etching of the larger textures 82 is completed. Therefore, the part of the textures 83 is not overetched. As a result, after removing the oxide film layer 7, the textures 82 and 83 having the designed shapes can be obtained as shown in FIG. 5(b).

As described in the foregoing, in the production of a solar cell comprising a substrate 4 having the larger textures 82 and the smaller textures 83 having bottom sides of different lengths arranged on the light-receiving surface of the substrate having cleavage directions perpendicular to each other by using a masking pattern, the textures 83 without overetching can be obtained by the manner that a masking pattern is formed with an oxide film layer 7 to have the line width d2 of the masking pattern positioned in the region for forming the smaller textures 83 that is larger than the line width d1 of the masking pattern positioned in the region for forming the larger textures 82, and the substrate is etched by using the masking pattern. The textures 84 and 85 shown in FIGS. 3(a) and 3(b) can also be obtained to have the designed shapes as similar to the foregoing case by setting the line width of the masking pattern.

A solar cell according to the present invention was produced by using the substrate 4 having these textures formed thereon and forming an N type impurity diffusion layer 3 (or a P type impurity diffusion layer), a front electrode 2, an oxide film 7 and an anti-reflection film 10 on the light-receiving surface of the substrate 4 and forming a P type impurity diffusion layer 5 (or an N type impurity diffusion layer), an oxide film 7 and a back electrode 6 on the non-light-receiving surface thereof.

As described in the foregoing, according to the embodiment of the invention, a solar cell having electronic characteristics and optical characteristics equivalent to the conventional products that exhibits small warpage and is difficult to be broken upon production and handling can be produced even by using an apparatus equivalent to those for the conventional process.

While the embodiments of the invention have been described for the solar cell using a P type silicon substrate, the invention can be applied to a solar cell using an N type substrate and other substrates than a silicon single crystal, such as GaAs. While the embodiments of the invention have been described for the silicon solar cell of an NRS/BSF type, the invention can be applied to a silicon solar cell of an NRS/LBSF type. The solar cell of the invention can be applied to a solar cell for use in the space and a solar cell for use on the ground.

For forming the arrangement of textures having discontinuous bottom sides along at least one cleavage direction, the masking pattern is formed so that the discontinuous bottom sides along the cleavage direction have different lengths, the width d1 of a line of the masking pattern located in a region for forming a texture 82 having a shorter bottom side is smaller than the width d2 of a line of the masking pattern located in a region for forming a texture 83 having a longer bottom side. Thereby, the etch speed is so controlled that, in the case where the textures of different sizes, i.e., textures with different bottom sides, are formed, over etch can be prevented and the yield can be improved.

In the case where textures are formed on a surface of a substrate having continuous cleavage directions in two directions perpendicular to each other in the solar cell of the invention, the textures are prevented from aligning in a straight line in both directions of the two cleavage directions, whereby breakage and warpage of the solar cell can be suppressed with the conventional anisotropic etching utilized.

According to the process for producing a solar cell of the invention, the productivity of the solar cell is improved and the resulting solar cell is convenient for handling.

What is claimed is:

1. A solar cell comprising a substrate having cleavage directions perpendicular to each other and having textures arranged on its light-receiving surface, said textures having bottom sides adjacent to each other along the cleavage directions and the bottom sides along at least one cleavage direction being discontinuous.

2. A solar cell according to claim 1, wherein said bottom sides are discontinuous in one of said cleavage directions, and said bottom sides along said discontinuous cleavage direction have the same length.

3. A solar cell according to claim 1, wherein said bottom sides are discontinuous in one of said cleavage directions, and said bottom sides along said discontinuous cleavage direction have different lengths.

4. A solar cell according to claim 1, wherein said bottom sides are discontinuous in both said cleavage directions, and said bottom sides along said discontinuous cleavage directions have different lengths.

5. A solar cell according to claim 2 or 4, wherein said textures are arranged to deviate in said discontinuous cleavage direction by a length of ½ of a length of said bottom side.

6. A solar cell according to one of claims 1 to 5, wherein said substrate has a rectangular shape, and one side of said substrate forms a prescribed angle with respect to said cleavage direction.

7. A solar cell according to any one of claims 1 to 6, wherein the substrate has a P type or N type diffusion layer, an oxide film layer and a front electrode on a light-receiving surface thereof and has an N type or P type diffusion layer and a back electrode on a non-light-receiving surface thereof.

8. A process for producing textures of a solar cell comprising a step of:
forming an oxide film layer on a light-receiving surface of a substrate having cleavage directions perpendicular to each other;
forming a masking pattern of the oxide film layer using a photo resist; and
etching the light-receiving surface of the substrate using the masking pattern, thereby forming an arrangement of textures on the surface of the substrate;
the masking pattern being formed so that the textures have bottom sides adjacent to each other along the cleavage directions and the bottom sides along at least one cleavage direction are discontinuous.

9. A process for producing textures according to claim 8, wherein, for forming an arrangement of textures having discontinuous bottom sides along at least one cleavage direction, the masking pattern is formed so that the discontinuous bottom sides along the cleavage direction have different lengths and a line width of the masking pattern located in a region for forming a texture having a shorter bottom side is larger than the line width of the masking pattern located in a region for forming a texture having a longer bottom side.
